(19) United States
(12) Patent Application Publication
(10) Pub. No.: US 2024/0086319 A1
(43) Pub. Date: Mar. 14, 2024

(54) VIRTUAL AND PHYSICAL EXTENDED MEMORY ARRAY

(71) Applicant: Micron Technology, Inc., Boise, ID (US)

(72) Inventors: Donald M. Morgan, Meridian, ID (US); Alan J. Wilson, Boise, ID (US); Bryan David Kerstetter, Kuna, ID (US)

(21) Appl. No.: 17/941,592

(22) Filed: Sep. 9, 2022

(51) Int. Cl. G06F 12/02; G11C 29/10

(52) U.S. Cl. CPC G06F 12/0292; G11C 29/10; G06F 2212/1032; G06F 2212/657

(57) ABSTRACT

A memory device for extending addressable array space by incorporating virtual and physical memory arrays is disclosed. When extra storage space beyond a physical memory array is needed by a controller of the memory device, the storage space may be provided by extending the address space using a virtual array. The memory device incorporates the use of an extra row address bit to increase the addressable space, whereby the extra bit is utilized to address virtual rows in the virtual array. Spare or redundant physical memory elements utilized for memory repair may be programmed to a virtual address space for the virtual memory array. When a memory device operation is activated, the extra row address bit is set to high, and the virtual row address matches with a spare or redundant memory element, the virtual row in the virtual array space is activated for performance of the operation.

### FIELD OF THE TECHNOLOGY

At least some embodiments disclosed herein relate to memory devices in general, and more particularly, but not limited to, a memory array capable of being extended both physically and virtually.

### BACKGROUND

Typically, a computing device or system includes one or more processors and one or more memory devices, such as memory chips or integrated circuits. The memory devices may be utilized to store data that may be accessed, modified, deleted, or replaced. The memory devices may be, for example, non-volatile memory devices that retain data irrespective of whether the memory devices are powered on or off. Such non-volatile memories may include, but are not limited to, read-only memories, solid state drives, and NAND flash memories. Additionally, the memory devices may be volatile memory devices, such as, but not limited to, dynamic or static random-access memories, which retain stored data while powered on, but are susceptible to data loss when powered off. Based on receipt of an input, the one or more processors of the computing device or system may request that a memory device of the computing system retrieve stored data associated with or corresponding to the input. In certain scenarios, the data retrieved from the memory device may include instructions, which may be executed by the one or more processors to perform various operations and may include data that may be utilized as inputs for the various operations. In instances where the one or more processors perform operations based on instructions from the memory device, data resulting from the performance of the operations may be subsequently stored into the memory device for future retrieval.

Despite the advancements provided by current memory technologies, there is an ever-increasing desire to increase the addressable memory space of a memory device without substantially increasing the memory device layout or die size. Additionally, memory devices often undergo stress events, which may cause damage to physical rows of the physical memory array of the memory device. For example, when a customer purchases a memory device and solders the memory device onto a printed circuit board or other componentry, there is a risk that certain memory device elements, such as physical rows of the physical memory array sustain damage or are rendered inoperable. Based at least on the foregoing, providing functionality to effectively address these desires and more, will provide enhanced memory device functionality, enhanced memory device versality, increase storage capabilities, and improved memory device failure mitigation capabilities.

### BRIEF DESCRIPTION OF THE DRAWINGS

The embodiments are illustrated by way of example and not limitation in the figures of the accompanying drawings in which like references indicate similar elements.

FIG. 1 illustrates a schematic diagram of a memory device and host device for providing a virtual and physical extended memory array in accordance with embodiments of the present disclosure.

FIG. 2 illustrates a schematic diagram illustrating a physical memory array of a memory device, redundant memory elements that may be programmed to replace faulty rows in the physical memory array or create physical rows in a virtual array space, and a virtual memory array of the memory device in accordance with embodiments of the present disclosure.

FIG. 3, illustrates an exemplary readout scheme for a mode register of a memory device that may be utilized to indicate availability of redundant memory elements in accordance with embodiments of the present disclosure.

FIG. 4 illustrates an exemplary flow relating to activating memory device operation through activation of physical rows in a physical memory array, activation of virtual rows in a virtual array, reporting redundant memory element availability, conducting post package repair, and conducting soft post package repair in accordance with embodiments of the present disclosure.

FIG. 5 illustrates a method for virtually and physically extending a memory array of a memory device in accordance with embodiments of the present disclosure.

FIG. 6 illustrates a schematic diagram of a machine in the form of a computer system within which a set of instructions, when executed, may cause the machine to facilitate functionality supporting virtually and physically extending a memory array of a memory device according to embodiments of the present disclosure.

### DETAILED DESCRIPTION

The following disclosure describes various embodiments for systems and methods for providing a virtual and physical extended memory array for a memory device. At least some embodiments of the present disclosure relate to memory device technologies for mitigating the effects and consequences of events that may cause damage to physical rows of a physical memory array of a memory device. Additionally, at least some embodiments relate to memory device technologies for increasing the addressable memory space of a memory device without having to increase the memory die size of the memory device. At least some embodiments of the present disclosure provide technological enhancements for addressing extra redundant or spare memory elements for additional useful purposes. The redundant memory elements may be utilized to replace malfunctioning or damaged physical rows in a physical memory array of a memory device, such as by remapping the addressing from the malfunctioning physical row to a redundant row of a redundant memory element of the memory device. In addition to facilitating the foregoing, the present disclosure also enables the redundant or spare memory elements to be matched to virtual rows in a virtual memory space of a virtual array of the memory device, substitute a physical row within a physical memory array of the memory device, or a combination thereof. The systems and methods may also include the ability to conduct post package repair and soft post package repair to create addressable physical rows within the virtual address space of the virtual array. In certain embodiments, the systems and methods may utilize the virtual address space of the virtual memory array and redundant memory elements to replace retired memory pages, as a scratch pad memory, for look up tables, or a combination thereof.

In certain embodiments, a memory device for extending the addressable array space of the memory device by incorporating virtual and physical memory arrays is provided. When extra storage space beyond a physical memory array is needed by a controller of the memory device, the storage space may be provided by extending the address space using a virtual array and matching virtual address space to redundant (or spare) memory elements of the memory device. In certain embodiments, the memory device incorporates the use of an extra row address bit to increase the addressable space, whereby the extra bit is utilized to address virtual rows in the virtual address space of the virtual array and serve as a match term for redundant row elements. Since the physical array density of the memory device does not increase, the new virtual address space of the virtual array provided in the present disclosure consists of virtual rows. In certain embodiments, when presenting addresses to the memory device with the extra bit high (e.g., charged to 1), the memory device may not select physical memory for an operation to be conducted with respect to the memory device (e.g., read, write, modify, erase, etc.). Instead, in certain embodiments, the memory device may select the virtual memory array.

In certain embodiments, if multiple memory pages reside on each redundant row element, then multiple virtual pages matched thereto may become physical. In certain embodiments, the memory device may be utilized to program unused redundant memory elements to match virtual rows in the virtual addressable space associated with the virtual array. In certain embodiments, the systems and methods may be configured to allow post package repair to program redundant memory elements to match virtual rows of the virtual memory array post package (i.e., after fabrication of the memory device). The post package repair may enable the controller of the memory device to create its own extra usable rows in the virtual space, such as by matching the redundant memory elements to virtual rows in the virtual space. In certain embodiments, the systems and methods may also be configured to allow soft post package repair to temporarily program redundant memory elements to match virtual rows of the virtual memory array post package. In such a scenario, when the memory device is powered down, the matching with the virtual rows may be lost, whereas for the post package repair, the matching may be maintained, such as in a non-volatile memory of the memory device.

In certain embodiments, the systems and methods may be configured to support functionality that reports the number of available extra redundant rows of redundant memory elements to a controller of the memory device. Based on this information, the controller may be configured to predict when the extra redundant rows will be exhausted (e.g., such as if the redundant rows are being matched to virtual rows or to physical rows). In certain embodiments, this information may also be utilized by the memory device to save remaining redundant memory elements for future potential repairs or matchings. Still further, the available number of extra redundant rows may be utilized by the controller of the memory device to adjust the size of the virtual address space associated with the virtual array in accordance with the changes in the redundant rows. In certain embodiments, partial density memory designs (e.g., 6 GB, 12 GB, etc.) may incorporate virtual address space already, and functionality provided by the systems and methods may be utilized to program redundant or spare memory elements to create physical pages for such designs. In such embodiments, the extra row address bit may not be required because the virtual address space may already be incorporated in such partial density memory designs. In certain embodiments, the systems and methods may be utilized to provide extra pages to allow page copy in wear leveling scenarios.

In certain embodiments, the systems and methods may include creating virtual address space of a virtual memory array and programming array elements (e.g., redundant, or spare memory elements) to respond to addresses in the virtual address space. In certain embodiments, the systems and methods may be configured to provide options to conduct pre-package (e.g., prior to complete fabrication or intermediate fabrication) and post package programming of redundant memory elements with virtual rows. In certain embodiments, the systems and methods may provide the options to conduct temporary or permanent programming, such as via soft post package repair or post package repair, respectively. In certain embodiments, a programmed redundant or spare element may provide multiple pages of storage area for the memory device. Based on at least the foregoing, the systems and methods of the present disclosure provide additional addressable memory beyond the physical memory array of a memory device to a controller without increasing the die size of the memory device, provide a way to address extra spare repair elements in a variety of ways, and provide increases to available extended memory.

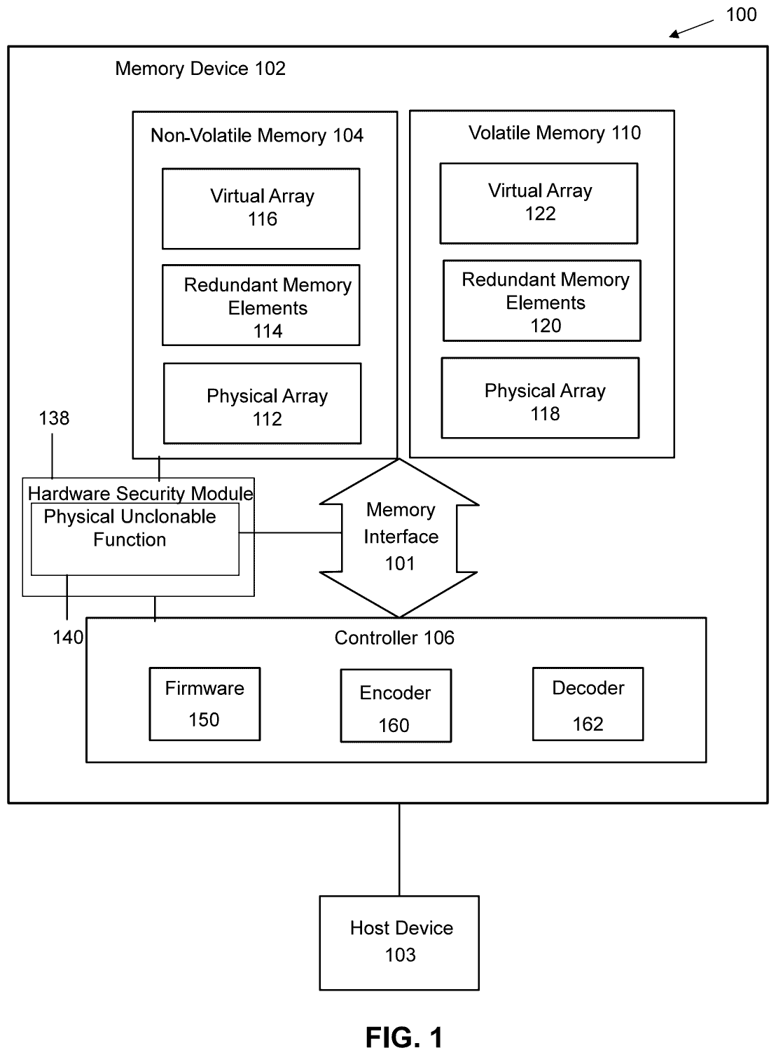

Referring now also to FIG. 1, FIG. 1 illustrates an exemplary architecture for a memory device 102 and host device 103 that may be utilized to provide a virtual and physical extended memory array accordance with embodiments of the present disclosure. The memory device 102 and other componentry illustrated in the Figures may belong to a system 100. In certain embodiments, the memory device 102 is, for example, but not limited to, an SSD, eMMC, memory card, or other storage device, or a NAND-based flash memory chip or module that is capable of encoding and decoding stored data, such as by utilizing an encoder 160 and decoder 162 of the memory device 102. In certain embodiments, the memory device 102 may include any amount of componentry to facilitate the operation of the memory device 102. In certain embodiments, for example, the memory device 102 may include, but is not limited to including, a non-volatile memory 104, which may include any number of memory blocks, a volatile memory 110, a memory interface 101, a controller 106 (which may include the encoder 160 and a decoder 162), a hardware security module 138, any other componentry, or a combination thereof. The memory device 102 may communicatively link with a host device 103, which may be or include a computer, server, processor, autonomous vehicle, any other computing device or system, or a combination thereof.

In certain embodiments, the non-volatile memory 104 may be configured to retain stored data irrespective of whether there is power delivered to the non-volatile memory 104. In certain embodiments, the non-volatile memory 104 may be configured to include any number of memory blocks that may be configured to store user data, any other type of data, or a combination thereof. In certain embodiments, the non-volatile memory 104 may be configured to include a physical memory array 112 including a plurality of physical memory cells configured to store data. In certain embodiments, the physical memory array 112 may be an array of bit cells, each of which may be configured to store a bit of data. In certain embodiments, each bit cell may be connected to a wordline and bitline. In certain embodiments, the memory cells of the non-volatile memory 104 may be etched onto the silicon wafer forming the base of the non-volatile memory. The memory cells may be etched in an array of columns (e.g., bitlines) and rows (e.g., wordlines). In certain embodiments, the intersection of a particular bitline with a wordline may serve as the address of the memory cell. In certain embodiments, for each combination of address bits, the memory device 102 may be configured to assert a wordline that activates the bit cells in a particular row. For example, in certain embodiments, when the wordline is high, the store bit may be configured to transfer to or from the bitline. On the other hand, in certain embodiments, when the wordline is not high, the bitline may be disconnected from the cell.

In certain embodiments, the non-volatile memory 104 may also be configured to include a plurality of redundant memory elements 114 (also referred to as spare memory elements). For example, during the manufacturing process, the memory device manufacturer may incorporate any number of redundant memory elements 114 (e.g., redundant or spare memory rows) with the memory device 102 to serve as replacements for malfunctioning or bad rows in the physical memory array 112. If a customer of the memory device manufacturer purchases a memory device including the non-volatile memory 104 and decides to affix the memory device 102 onto a printed circuit board or other componentry, there runs the risk that physical rows of the physical memory array 112 may malfunction, wear out, experience damage, or otherwise be rendered inoperable. For example, if the memory device 102 is soldered into the printed circuit board, the heat from the soldering may serve as a stress event to the physical rows of the physical memory array 112 such that one or more physical rows wear out or sustain damage. In such a scenario, any number of redundant memory elements 114 may be programmed, such as by the controller 106, to replace any number of damaged or inoperable physical rows from the physical array 112. In certain embodiments, the redundant memory elements 114 may be utilized to create physical rows corresponding to virtual rows in a virtual address space of a virtual memory array 116. In such a scenario, the redundant memory elements 112 may be utilized to expand the address space in the memory device 102. In certain embodiments, componentry of the memory device 102 may be configured to determine the number of available redundant memory elements 114 that may be programmed for other purposes. For example, the controller 106, which is discussed in further detail below, may keep track of the number of available redundant memory elements 114.

In certain embodiments, the non-volatile memory 104 may also be configured to include a virtual memory array 116 that may be utilized to extend the amount of addressable memory space of the memory device 102 via a virtual address space associated with the virtual memory array 116. For example, the virtual address space may be helpful in replacing retired physical memory pages, serving as scratch pad memory, providing look-up table functionality, among other helpful purposes. Much like the physical memory array 112, the virtual memory array 116 may include a plurality of rows, however, instead of being physical rows, the rows of the virtual memory array 116 may be virtual rows. In certain embodiments, the virtual rows may be matched to physical rows, such as to physical rows of the redundant memory elements 114. In certain embodiments, the memory device 102 may incorporate the use of an extra row address bit to reference the virtual address space of the virtual memory array 116 to effectively increase the addressable space of the memory device 102. For example, in certain embodiments, the extra row address bit may be utilized to double the original addressable space that is provided by the physical memory array 112. Since the array density does not double in size with virtual memory array 116, the new addressable space may consist of virtual rows rather than physical rows. In certain embodiments, when the extra row address bit is high (e.g., charged to 1), the memory device 102 may be configured to select a virtual row of the virtual memory array instead of a physical row of the physical memory array 112 for a transaction, such as a transaction initiated by a host device 103.

In certain embodiments, the extra row address bit may be utilized as a match term for the redundant memory elements 114. As a result, the redundant rows of the redundant memory elements 114 may be programmed by the controller 106 of the memory device 102 to match virtual rows of the virtual memory array 116 of the memory device 102. In certain embodiments, if multiple memory pages reside on each redundant row element, then multiple virtual pages may become physical. In certain embodiments, each row element may provide 128 physical pages. In certain embodiments, the memory device 102 may utilize unused redundant memory elements 114 to match virtual rows in the virtual addressable space of the virtual memory array 116. In certain embodiments, the memory device 102 may utilize post package repair to program the redundant memory elements 114 to match the virtual rows of the virtual memory array 116 post package (i.e., after the memory device 102 has been fabricated by the manufacturer). In certain embodiments, the address of the failing physical row may be remapped to a virtual row matched with a redundant memory element 114. In certain embodiments, post package repair may provide a form of self-healing capability to the memory device 102, whereby the location, address, or both, of a failing or damaged physical row of the physical memory array 112 is disabled at the hardware level so that a redundant memory element 114 may be persistently (or permanently) utilized in place of the failing or damaged physical row. In certain embodiments, the post package repair functionality may enable the controller 106 to create its own extra usable rows in the virtual address space of the virtual memory array 116.

In certain embodiments, the memory device 102 may utilize soft post package repair. Soft post package repair may be similar to post package repair, however, with soft post package repair the memory device 102 may be configured to repair damaged or failing physical rows using redundant memory elements 114 via non-persistent methods, such as by utilizing volatile memory 110. For example, with soft post package repair, the failing physical row may be remapped to a virtual row matched with a redundant memory element 114, but upon powering down the memory device 102, the mapping and repair may be lost. Similarly, with soft post package repair, the failing physical row may be remapped to a redundant memory element 114, but upon power down the memory device 102, the mapping and repair may be lost. As a result, soft post package repair may be utilized to temporarily program redundant memory elements 114 to match virtual rows of the virtual memory array 116 post package.

In certain embodiments, the controller 106 of the memory device 102 may be configured to control access to the non-volatile memory 104, the volatile memory 110, the hardware security module 138, any other componentry of the memory device 102, or a combination thereof. In certain embodiments, user data may be provided by controller 106 to the non-volatile memory 104, the volatile memory 110, or a combination thereof, such as by utilizing memory interface 101. For example, the user data may be obtained from the host device 103 to be stored in the non-volatile memory 104, such as in a memory block. In certain embodiments, the controller 106 may include an encoder 160 for generating ECC data (e.g., such as when writing data to the non-volatile memory 104), and a decoder 162 for decoding ECC data (e.g., when reading data, such as from the non-volatile memory 104). In certain embodiments, the controller 106 may include firmware 150, which may be configured to control the components of the system 100. In certain embodiments, the firmware 150 may be configured to control access to the non-volatile memory 104, the volatile memory 110, or a combination thereof, by the host device 103 and control the operative functionality of the memory device 102. Further details relating to the firmware 150 are discussed below.

As indicated above, the memory device 102 may be configured to receive data (e.g., user data) to be stored from host device 103 (e.g., over a serial communications interface, or a wireless communications interface). In certain embodiments, the user data may be video data from a device of a user, sensor data from one or more sensors of an autonomous or other vehicle, text data, audio data, virtual reality data, augmented reality data, information, content, any type of data, or a combination thereof. In certain embodiments, memory device 102 may be configured to store the received data in memory cells of non-volatile memory 104, the volatile memory 110, or a combination thereof. In certain embodiments, the memory cells may be provided by one or more non-volatile memory chips, volatile memory chips, or a combination thereof. In certain embodiments, the memory chips may be NAND-based flash memory chips, however, any type of memory chips or combination of memory chips may also be utilized. In certain embodiments, the memory device 102 may be configured to store received data in volatile memory 110 (which may be any type of volatile memory) on a non-persistent basis. In certain embodiments, the volatile memory 110 may include componentry, such, as but not limited to, physical memory array 118, redundant memory elements 120, and virtual memory array 122, which may be configured to function similarly to the corresponding physical memory array 112, redundant memory elements 114, and the virtual memory array 116 of the non-volatile memory 104.

In certain embodiments, the memory device 102 may include any number of hardware security modules (HSMs) 138. In certain embodiments, the HSM 138 may include an interface that facilitates communications to and from the host device 103. In certain embodiments, the interface can comprise a Peripheral Component Interconnect Express (PCIe) interface or other interface. In certain embodiments, the interface can comprise other similar types of interfaces such as a Non-Volatile Memory Express (NVMe), NVMe over Fiber (NVMeOF), Serial Peripheral Interface (SPI), or similar bus. In certain embodiments, HSM 138 may be configured to receive commands from host device 103, such as via interface 101 or via its own interface. In certain embodiments, the commands can comprise commands that are to be executed in a secure manner. For example, the commands can comprise commands to generate or derive cryptographic keys, read cryptographic keys, encrypt or decrypt data, generate digital signatures, etc. In certain embodiments, any commands currently executable by existing HSMs can be received via interface 101.

In certain embodiments, the HSM 138 may include a volatile storage area. In certain embodiments, the volatile storage area can comprise any type of memory that loses data stored therein when the memory device 102 is powered off or if power to the volatile storage area falls below a threshold for sustaining the volatile storage area operation. For example, the volatile storage area can comprise a dynamic random-access memory (DRAM), static random-access memory (SRAM), or similar types of volatile storage area technologies. In certain embodiments, the HSM 138 may utilize the volatile storage area to store cryptographic data (e.g., keys, seeds, results, authentication information, identities, etc.). In certain embodiments, since the volatile storage area may lose data when powered off, the HSM 138 may not persistently store sensitive data when powered off. In certain embodiments, the volatile storage area can comprise a register file or may comprise a DRAM or SRAM and one or more registers.

In certain embodiments, HSM 138 may include a physical unclonable or physically unclonable function (PUF) 140. In certain embodiments, the PUF 140 may comprise a physical hardware circuit that exploits inherent randomness introduced during manufacturing to give a physical entity a unique ‘fingerprint’ or trust anchor. In certain embodiments, the PUF 140 may produce a consistent and repeatable value. In certain embodiments, the PUF 140 may comprise a SRAM PUF, Delay PUF, or any other PUF technology implemented on the HSM 138. In certain embodiments, the HSM 138 may create a PUF 140 from a portion of uninitialized memory space in the volatile storage area that is not subsequently used for any other purpose. Thus, the PUF 140 value may be related to the random value of the portion of the memory space in the volatile storage area. In certain embodiments, by not storing keys, the HSM 138 may not be susceptible to offline attacks. Further, in certain embodiments, security requirements can be relaxed since keys are only stored in volatile storage area and not persistent memory.

In certain embodiments the firmware 150 of the memory device 102 may be configured to control the operative functionality of the memory device 102. In certain embodiments, the firmware 150 may be configured to manage all operations conducted by the controller 106. In certain embodiments, the firmware 150 may be configured to facilitate matching of virtual rows of the virtual memory array 116 with redundant rows of the redundant memory elements 114. In certain embodiments, the firmware 150 may be configured to facilitate matching of redundant rows of the redundant memory elements 114 with physical rows of the physical memory array 112. In certain embodiments, the firmware 150 may be configured to facilitate post package repair, soft post package repair, or a combination thereof, to match a supplied row address to a redundant memory element 114 to create an addressable physical row within a virtual address space of the virtual memory array 116, to substitute a physical row of the physical memory array 112 (e.g., of the physical row failed) with a redundant row of the redundant memory elements 114. In certain embodiments, the firmware 150 may be configured to determine whether the extra row address bit is high or not. In certain embodiments, the firmware 150 may be configured to activate a physical row in the physical memory array 112, activate a virtual row in the virtual memory array 116, or ignore an activation request based on various detected conditions (e.g., the firmware 150 determines that a virtual row does not match with a redundant row of a redundant memory element 114 when the extra row address bit is determined to be high). Notably, the system 100 including the memory device 102 may be utilized to support any of the functionality provided by the present disclosure.

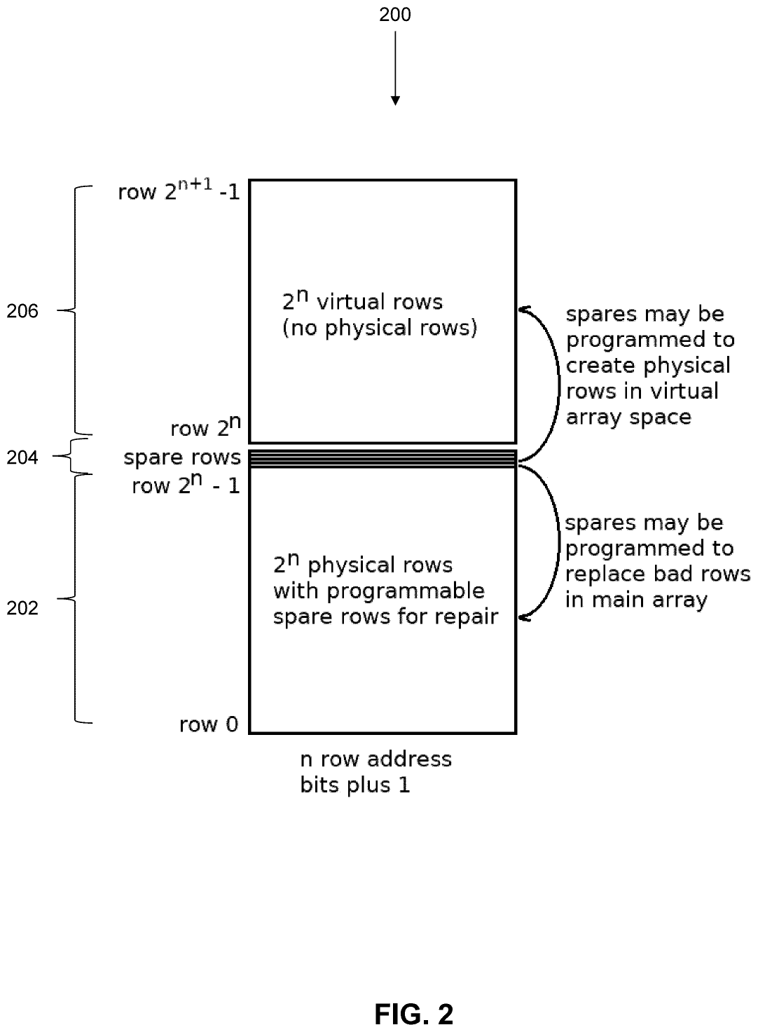

Referring now also to FIG. 2, a schematic diagram of a portion of a memory device 200 (e.g. memory device 102) illustrating a physical memory array 202 (e.g., physical memory array 112) of a memory device, redundant memory elements 204 (e.g., redundant memory elements 114) that may be programmed to replace bad rows in the physical memory array or create physical rows in a virtual array space, and a virtual memory array 206 (e.g., virtual memory array 116) of the memory device in accordance with embodiments of the present disclosure is shown. In certain embodiments, the memory device 200 may be memory device 102 or may be included within system 100. The schematic diagram depicts an exemplary physical memory array 202, redundant (i.e., spare) memory elements 204, and virtual memory array 206 of a memory device 102. In certain embodiments, the spare rows and spare memory elements may be equivalent to redundant rows and redundant memory elements 114, as described in the present disclosure. In certain embodiments, the physical memory array 202 may be configured to have 2ⁿ physical rows with programmable redundant rows 204 that may be utilized for repair and other purposes. Illustratively, as shown, there may be n row address bits plus 1 and the rows may include row 0 through row 2ⁿ-1. In certain embodiments, for example, the redundant rows 204 (e.g., spare rows) may be programmed by the memory device 200 (or memory device 102) to replace bad rows (e.g., damaged, or inoperable rows) in the physical array 202 (or physical array 112). In certain embodiments, the virtual rows of the virtual memory array 206 may start at 2ⁿ and may go through row 2ⁿ⁺¹-1, as shown in FIG. 2. The virtual rows, which may not include physical rows, may be utilized to increase the addressable space of the memory device 200. In certain embodiments, the redundant memory elements 204 may be programmed to create physical rows in the virtual array space including the virtual rows. In certain embodiments, the programming may be accomplished by matching the redundant rows of the redundant memory elements 204 with the virtual rows.

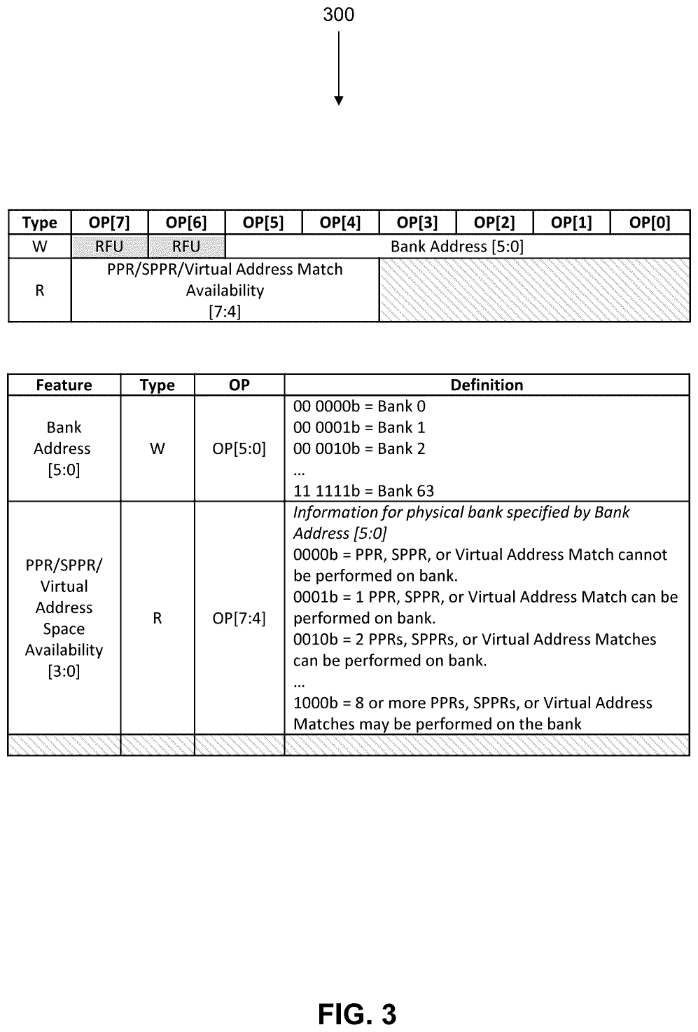

Referring now also to FIG. 3, an exemplary readout scheme for a mode register 300 of a memory device (e.g., memory device 200, 100, or both), which may be utilized to indicate availability of redundant memory elements 114 in accordance with embodiments of the present disclosure is shown. In certain embodiments, the mode register 300 may correspond with mode register 29 (MR29) and may be utilized for physical row expansion into the virtual addressable space. In certain embodiments, the mode register 300 may be configured to provide a redundant memory element availability that may be utilized by the controller 106 to determine how many available redundant memory elements 114 are left for repurposing (e.g., for replacing physical rows of the physical memory array 112 or being matched with virtual rows of the virtual memory array 116). In certain embodiments, readout functionality provided by a memory device may be utilized to read out the availability of redundant memory elements 114. In certain embodiments, as described herein, the redundant memory elements 114 may be utilized for post package repair, soft post package repair, as a virtual address match, or a combination thereof. In certain embodiments, the availability of the current value of the readout may be current as of device powerup, device reset, after a post package repair, or a combination thereof. In certain embodiments, per-memory bank availability readout for post package repair, soft post package repair, and virtual address match readout may be granted.

In certain embodiments, for a write, the memory bank address may occupy opcodes [0:5] and RFUs (Reserve for Future Use) may occupy [6:7]. For example, there may be 64 banks of memory and 00 0000b=Bank 0, 00 0001b=Bank 1, 00 0010b=Bank 2, and so on until 11 1111b, which=Bank 63, as shown in FIG. 3. As a result, information for a physical memory bank may be specified via bank address [5:0] of the mode register 300. In certain embodiments, for a read, the opcodes [7:4] may be utilized for indicating redundant memory element 114 availability for post package repair, soft post package repair, virtual address match, or a combination thereof. For example, for 0000b may indicate that a post package repair, a soft post package repair, or a virtual address matching cannot be performed on a memory bank; 0001b may indicate that 1 post package repair, 1 soft post package repair, or 1 virtual address match may be performed on a memory bank; 0010b may indicate that 2 post package repairs, 2 soft post package repairs, or 2 virtual address matchings may be performed on the memory bank; 0011b may indicate that 3 post package repairs, 3 soft post package repairs, or 3 virtual address matchings may be performed on the memory bank; 0100b may indicate that 4 post package repairs, 4 soft post package repairs, or 4 virtual address matchings may be performed on the memory bank; 0101b may indicate 5 post package repairs, 5 soft post package repairs, or 5 virtual address matchings may be performed on the bank; 0110b may indicate 6 post package repairs, 6 soft post package repairs, or 6 virtual address matchings may be performed on the bank; 0111b may indicate 7 post package repairs, 7 soft post package repairs, or 7 virtual address matchings may be performed on the bank; and 1000b may indicate that 8 or more post package repairs, 8 or more soft post package repairs, or 8 or more virtual address matchings may be performed on the bank. In certain embodiments, the mode register 300 values may be updated in real time as the redundant rows of redundant memory elements 114 are used to replace physical rows of the physical memory array 112, used to match with virtual rows of the virtual memory array 116, or are otherwise used up by the memory device 102. In certain embodiments, the last 8 repairs per bank may be reserved for repair or physical row expansion in the virtual space by the controller 106 of the memory device 102.

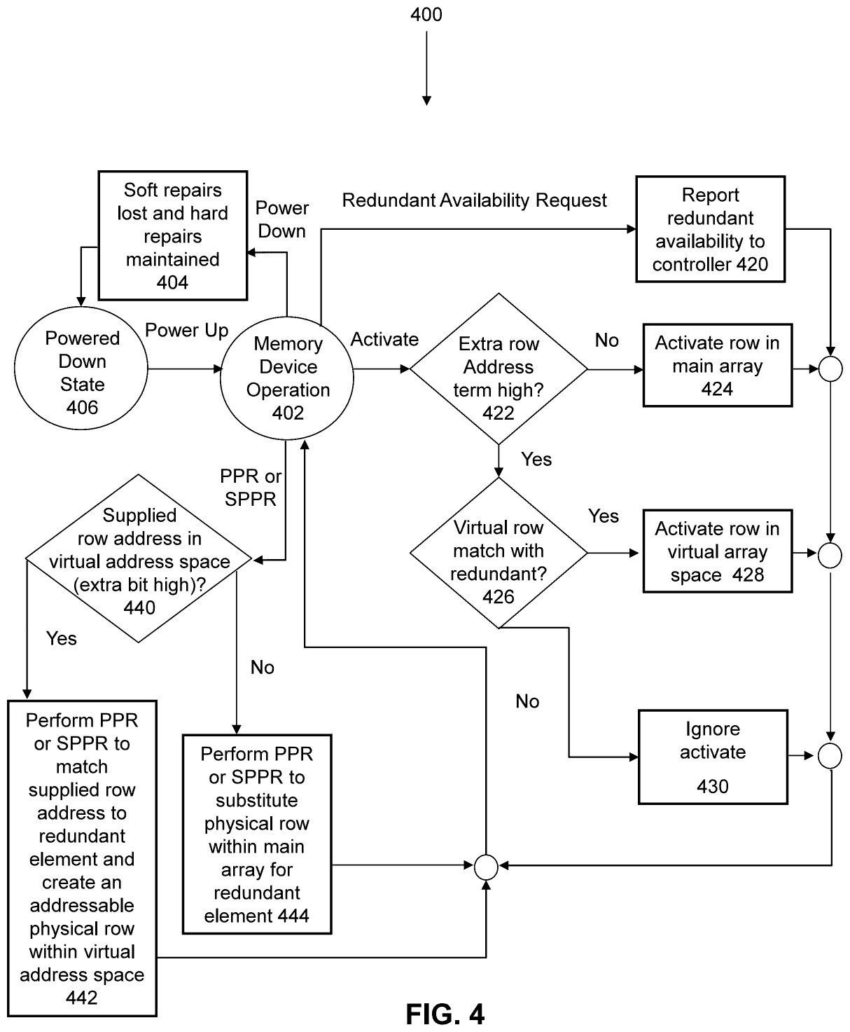

Referring now also to FIG. 4, FIG. 4 illustrates an exemplary flow 400 relating to activating memory device operation through activation of physical rows in a physical memory array 112, activation of virtual rows in a virtual memory array 116, reporting redundant memory element 114 availability, conducting post package repair, and conducting soft post package repair in accordance with embodiments of the present disclosure. At 402, memory device operation may serve as an initial part of each process flow in flow 400. For example, the memory device 102 may be operating at 402 and then a power down of the memory device 102 may be initiated. At 404, as the memory device 102 is powering down or has powered down, data stored in volatile memory 110 may be lost. For example, any soft post package repairs (e.g., by matching a redundant memory element 114 with a virtual row of the virtual memory array 116 and storing the address mapping information in the volatile memory 110). For mappings stored in the non-volatile memory 104, however, the post package repairs conducted may be maintained since mappings of redundant rows with virtual rows or physical rows may be stored in the non-volatile memory, which is persistent and can store data even after a power down event. At 406, the memory device may enter a powered down state. Then, the memory device 102 may be powered up again and may enter the memory device operation stage or state 402. In certain embodiments, at 402, the memory device 102 may be configured to provide a redundant availability request, which may be utilized to report the current redundant memory element 114 availability to the controller 106 of the memory device 102, such as by utilizing the mode register 300.

In certain embodiments, at 402, the memory device 102 may be issued an activate, such as via a command from a host device 102 to perform a transaction using the memory device 102. For example, the transaction may be to conduct operations, such as, but not limited to, writing data to the memory device 102, reading data from the memory device 102, accessing the memory device 102, performing any other operation with respect to the memory device 102, or a combination thereof. For example, the transaction may be intended for a specific address in the memory device 102. At 422, the memory device 102 may determine whether the extra row address bit is high (e.g., charged to 1 or contains value of 1). If the extra row address bit is not high, the flow 400 may proceed to 424. At 424, the flow 400 may include activating a physical row in the physical memory array 112 for the transaction. If, however, the extra row address bit is high, the memory device 102, such as via the controller 106, may determine whether there is a virtual row matched with a redundant row of a redundant memory element 114 corresponding to the address, at 426. If, at 426, there is a virtual row matched with a redundant row of a redundant memory element 114, the flow 400 may proceed to activate the virtual row in the virtual array space, at 428. If, at 426, the virtual row does not match with a redundant row of a redundant memory element 114, the flow 400 may proceed to 430. At 430, the memory activation for the transaction may be ignored by the memory device 102.

In certain embodiments, at 402, the flow 400 may be configured to conduct post package repair or soft post package repair. For example, at 440, the memory device 102 may be configured to determine whether a supplied row address is in a virtual address space with the extra row address bit at high. If the extra row address bit is at high, the flow 400 may proceed to 442. At 442, the flow 400 may include having the memory device 102 perform post package repair or soft post package repair to match the supplied row address to a redundant row of a redundant memory element 114 to facilitate creation of an addressable physical row within the virtual address space of the virtual memory array 116. If, however, the supplied row address is not in the virtual address space and/or the extra row address bit is not high, the flow 400 may proceed to 444. At 444, the flow 400 may include performing post package repair or soft post package repair to substitute a physical row of the physical memory array 112 with a redundant row of a redundant memory element 114. The flow 400 may be configured to be modified to include or remove any functionality described herein.

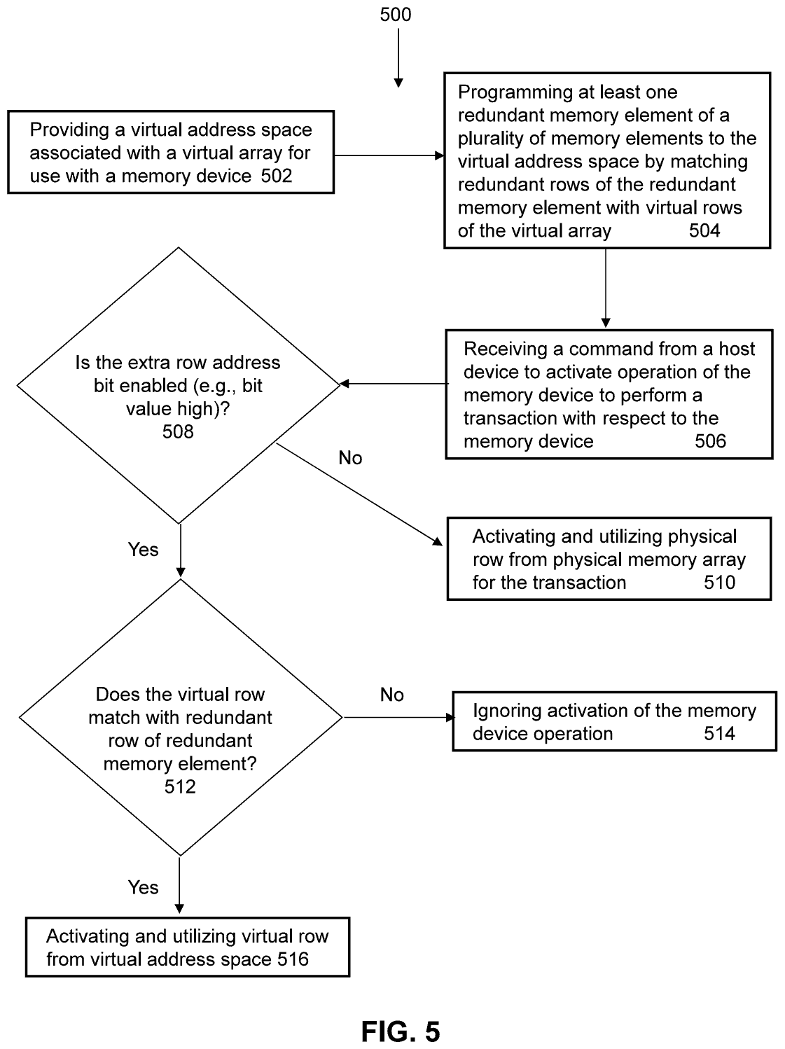

Referring now also to FIG. 5, FIG. 5 illustrates an exemplary method 500 for providing utilizing a virtual and physical extended memory array according to embodiments of the present disclosure. For example, the method of FIG. 5 can be implemented in the system 100 of FIG. 1 and any of the other systems or devices illustrated in the Figures. In certain embodiments, the method of FIG. 5 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method of FIG. 5 may be performed at least in part by one or more processing devices (e.g., controller 106 of FIG. 1). Although shown in a particular sequence or order, unless otherwise specified, the order of the processes may be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

The method 500 may include steps for providing a virtual and physical extended memory array according to various embodiments of the present disclosure. In certain embodiments, the method 500 may be performed by utilizing the system 100, by utilizing any combination of the componentry contained therein, or a combination thereof. At step 502, the method 500 may include providing a virtual address space associated with a virtual array for use with a memory device including a physical memory array and redundant memory elements that may be utilized to map with virtual rows of the virtual address space, replace damaged physical rows of the physical memory array, or a combination thereof. At step 504, the method 500 may include programming at least one redundant memory element of a plurality of memory elements to the virtual address space by matching or mapping redundant rows of the redundant memory with virtual rows to the virtual array.

At step 506, the method 500 may include receiving a command from a host device to activate operation of the memory device to perform a transaction with respect to an address of the memory device. The transaction, for example, may include, but is not limited to, a read, a write, an erase, an access, any other transaction, or a combination thereof. At step 508, the method 500 may include determining if the extra row address bit is enabled (e.g., the bit value is high). If the extra address row address bit is not high, the method may, at step 510, include activating and utilizing a physical row from the physical memory array for the transaction. If, however, at step 508, the method 500 has the extra row address bit enabled, the method 500 may proceed to step 512. At step 512, the method 500 may include determining whether the virtual row matches with a redundant row of a redundant memory element. If there is no match, the method 500 may proceed to step 514, which includes ignoring the activation of the memory device operation. If, however, at step 512, the virtual row does match with the redundant row of a redundant memory element, the method 500 may proceed to step 516, which may include activating and utilizing the virtual row form the virtual address space for the operation. The method 500 may be repeated as desired and may incorporate any of the other functionality of the present disclosure and is not limited to the specific sequences of steps provide herein.

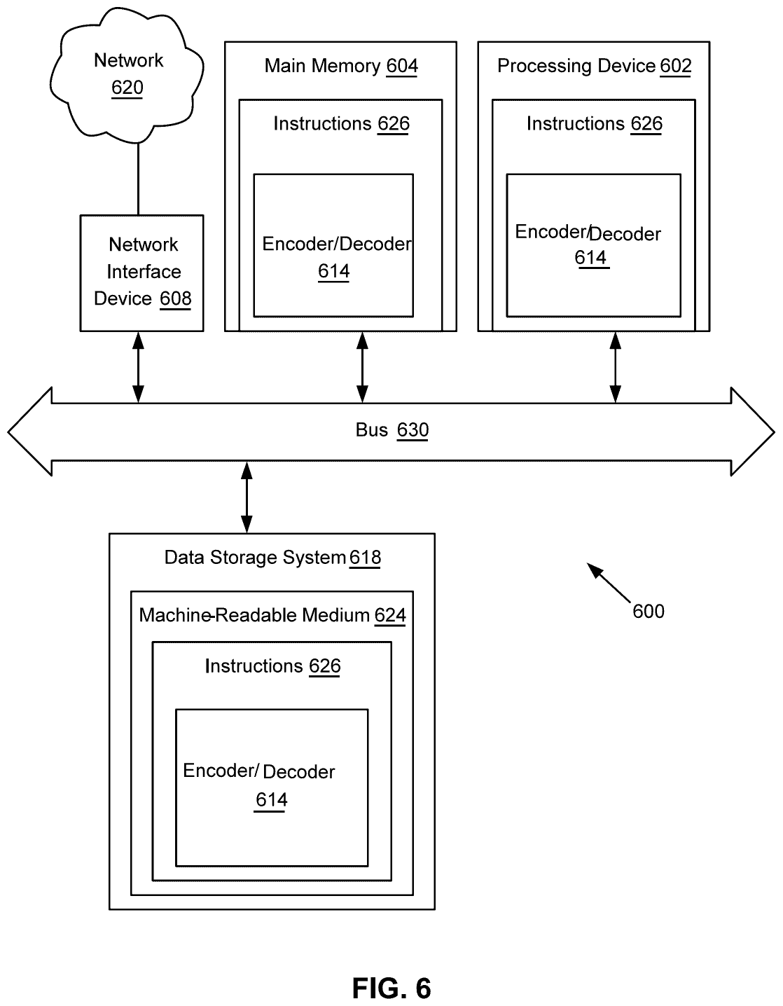

FIG. 6 illustrates an exemplary machine of a computer system 600 within which a set of instructions, for causing the machine to perform any one or more of the methodologies discussed herein, can be executed. In certain embodiments, the computer system 600 can correspond to a host system or device (e.g., the host device 103 of FIG. 1) that includes, is coupled to, or utilizes a memory system (e.g., the memory device 102 of FIG. 1). In certain embodiments, computer system 600 corresponds to memory device 102, host device 103, or a combination thereof. In certain embodiments, the machine may be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment. In certain embodiments, the machine may be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

In certain embodiments, the exemplary computer system 600 may include a processing device 602, a main memory 604 (e.g., read-only memory (ROM), flash memory, dynamic random-access memory (DRAM) such as synchronous DRAM (SDRAM) or Rambus DRAM (RDRAM), static random-access memory (SRAM), etc.), and/or a data storage system 618, which are configured to communicate with each other via a bus 630 (which can include multiple buses). In certain embodiments, processing device 602 may represent one or more general-purpose processing devices such as a microprocessor, a central processing unit, or the like. More particularly, the processing device may be a complex instruction set computing (CISC) microprocessor, reduced instruction set computing (RISC) microprocessor, very long instruction word (VLIW) microprocessor, or a processor implementing other instruction sets, or processors implementing a combination of instruction sets. In certain embodiments, the processing device 402 may also be one or more special-purpose processing devices such as an application specific integrated circuit (ASIC), a field programmable gate array (FPGA), a digital signal processor (DSP), network processor, or the like.

The processing device 602 is configured to execute instructions 626 for performing the operations and steps discussed herein. For example, the processing device 602 may be configured to perform steps of flow 400 and the method 500 and support functionality provided by the system 100. For example, in certain embodiments, the computer system 600 may be configured to assist in activating physical or virtual rows in a physical array or virtual array respectively, determining whether a virtual row matches with a redundant row of a redundant memory element of a memory device, determine whether a supplied row address is found in the virtual address space, conducting post package repair or soft post package repair to match supplied row addresses to redundant rows of redundant memory elements, conducting post package repair or soft post package repair to substitute physical rows within a main physical array with redundant rows of redundant memory elements, activating or deactivating operation of the memory device 102, reporting redundant memory element availability, performing any other operations as described herein, or a combination thereof. As another example, in certain embodiments, the computer system 600 may assist with conducting the operative functionality of the controller 106. In certain embodiments, computer system 600 may further include a network interface device 608 to communicate over a network 620.

The data storage system 618 can include a machine-readable storage medium 624 (also referred to as a computer-readable medium herein) on which is stored one or more sets of instructions 626 or software embodying any one or more of the methodologies or functions described herein. The instructions 626 can also reside, completely or at least partially, within the main memory 604 and/or within the processing device 602 during execution thereof by the computer system 600, the main memory 604 and the processing device 602 also constituting machine-readable storage media. The machine-readable storage medium 624, data storage system 618, and/or main memory 604 can correspond to the memory device 102, or a combination thereof.

Reference in this specification to “one embodiment” “an embodiment” or “certain embodiments” may mean that a particular feature, structure, or characteristic described in connection with the embodiment is included in at least one embodiment of the disclosure. The appearances of the phrases “in one embodiment” and “in certain embodiments” in various places in the specification are not necessarily all referring to the same embodiment(s), nor are separate or alternative embodiments mutually exclusive of other embodiments. Moreover, various features are described which may be exhibited by some embodiments and not by others. Similarly, various requirements are described which may be requirements for some embodiments, but not other embodiments.

Although some of the drawings illustrate a number of operations in a particular order, operations which are not order dependent may be reordered and other operations may be combined or broken out. While some reordering or other groupings are specifically mentioned, others will be apparent to those of ordinary skill in the art and so do not present an exhaustive list of alternatives. Moreover, it should be recognized that the stages could be implemented in hardware, firmware, software, or any combination thereof.

In the foregoing specification, the disclosure has been described with reference to specific exemplary embodiments thereof. It will be evident that various modifications may be made thereto without departing from the broader spirit and scope as set forth in the following claims. The specification and drawings are, accordingly, to be regarded in an illustrative sense rather than a restrictive sense.

What is claimed is:

1. A memory device, comprising:
a physical array;
a plurality of redundant memory elements; and
a controller;
wherein the controller is configured to program at least one redundant memory element of the plurality of redundant memory elements of the memory device to a virtual addressable space by matching redundant rows of the at least one redundant memory element with virtual rows of a virtual array associated with the virtual addressable space;
wherein the controller is configured to receive a command to activate operation of the memory device to perform a transaction associated with the command associated with an address of the memory device;
wherein the controller is configured to determine whether an extra row address bit for the address is enabled after receipt of the command;
wherein the controller is configured to determine, if the extra row address bit for the address is enabled, whether a virtual row associated with the address matches a redundant row of the at least one redundant memory element;
wherein the controller is configured to activate the virtual row in the virtual array for the transaction based on a determination that the virtual row associated with the address matches the redundant row; and
wherein the controller is configured to activate a physical row in the physical array if the extra row address bit for the address is not enabled.

2. The memory device of claim 1, wherein the controller is further configured to ignore the command to activate operation of the memory device if the virtual row associated with the address does not match the redundant row of the at least one redundant memory element.

3. The memory device of claim 1, wherein the controller is further configured to activate a physical row within the physical array if the extra row address bit for the address is not enabled.

4. The memory device of claim 1, wherein the controller is further configured to receive information from the memory device indicating a current availability of redundant memory elements of the plurality of redundant memory elements.

5. The memory device of claim 4, wherein the controller is configured to receive the information indicating the current availability of the redundant memory elements from a mode register of the memory device.

6. The memory device of claim 1, wherein the controller is configured to perform a post package repair to match a supplied row address to a redundant memory element of the plurality of redundant memory elements, wherein if the supplied row address is in the virtual address space the extra row address bit is enabled.

7. The memory device of claim 6, wherein the controller is configured to create an addressable physical row within the virtual address space based on performing the post package repair.

8. The memory device of claim 1, wherein the controller is configured to perform a soft post package repair to match a supplied row address to a redundant memory element of the plurality of redundant memory elements, wherein if the supplied row address is in the virtual address space the extra row address bit is enabled.

9. The memory device of claim 1, wherein the controller is further configured to perform a post package repair to substitute a physical row in the physical array with a redundant memory element of the plurality of redundant memory elements, wherein if the supplied row address is in the physical address space the extra row address bit is not enabled.

10. The memory device of claim 1, wherein the controller is configured to perform a soft post package repair to substitute a physical row in the physical array with a redundant memory element of the plurality of redundant memory elements, wherein if the supplied row address is in the physical address space the extra row address bit is not enabled.

11. The memory device of claim 1, wherein the controller is configured to facilitate powering down of the memory device.

12. The memory device of claim 11, wherein the controller is configured to maintain a post package repair, lose a soft package repair, or a combination thereof, after the memory device is powered down.

13. The memory device of claim 1, wherein the controller is configured to predict when the plurality of redundant memory elements of the memory device will no longer be available to substitute physical rows of the physical array or be available to match with the virtual rows of the virtual array.

14. The memory device of claim 1, wherein the controller is configured to save redundant memory elements of the memory device for a future repair associated with the memory device.

15. A method, comprising:
programming, by utilizing a controller of a memory device, at least one redundant memory element of a plurality of redundant memory elements of the memory device to a virtual addressable space by matching redundant rows of the at least one redundant memory element with virtual rows of a virtual array associated with the virtual addressable space;
receiving, by utilizing the controller of the memory device, a command from a host device to activate operation of the memory device to perform a transaction associated with the command associated with an address of the memory device;
determining, by utilizing the controller of the memory device and in response to receipt of the command, whether an extra row address bit for the address is enabled;
determining, by utilizing the controller of the memory device and if the extra row address bit for the address is enabled, whether a virtual row associated with the address matches a redundant row of the at least one redundant memory element; and
activating, by utilizing the controller of the memory device, the virtual row in the virtual array for the transaction based on a determination that the virtual row associated with the address matches the redundant row.

16. The method of claim 15, further comprising reporting, by utilizing the memory device, a quantity of available redundant memory elements of the plurality of redundant memory elements.

17. The method of claim 15, wherein the programming of the at least one redundant memory element creates at least one physical row in the virtual addressable space, and wherein each physical row of the at least one physical row contains at least one physical page.

18. The method of claim 15, further comprising adjusting, by utilizing the controller of the memory device, a size of the virtual array as a quantity of available redundant memory elements of the plurality of redundant memory elements changes over time.

19. The method of claim 15, further comprising activating, by utilizing the controller of the memory device, a physical row within a physical array of the memory device if the extra row address bit for the address is not enabled.

20. The method of claim 15, further comprising perform, by utilizing the controller of the memory device, a post package repair to match a supplied row address in the virtual addressable space to a redundant memory element of the plurality of redundant memory elements if the supplied row address has the extra row address bit enabled.

21. A system, comprising:
a host device; and
a memory device including a physical array and configured to store data and include an addressable space of the memory device including a physical addressable space corresponding to a physical array including physical rows and a virtual addressable space corresponding to a virtual array including virtual rows, the memory device comprising;
a controller;
wherein the controller is configured to program at least one redundant memory element of a plurality of redundant memory elements of the memory device to the virtual addressable space by matching redundant rows of the at least one redundant memory element with virtual rows of the virtual array associated with the virtual addressable space;
wherein the controller is configured to create at least one addressable physical row within the virtual address space based on the programming of the at least one redundant memory element with the virtual rows;
wherein the controller is configured to receive a command from the host device to to perform a transaction associated with an address of the memory device; and
wherein the controller is configured to utilize the at least one addressable physical row within the virtual addressable space for the transaction if the address of the memory device associated with the transaction matches a virtual address programmed to the at least one addressable physical row.

22. The system of claim 21, wherein the programming of the at least one redundant memory element creates at least one physical row in the virtual addressable space, and wherein each physical row of the at least one physical row contains at least one physical page.
